(19) United States
(12) Patent Application Publication
(10) Pub. No.: US 2025/0062723 A1
(43) Pub. Date: Feb. 20, 2025

(54) AMPLIFIER DEVICES HAVING MULTIPLE BIAS NETWORKS

(71) Applicant: NXP USA, Inc., Austin, TX (US)

(72) Inventor: Anthony Lamy, Tournefeuille (FR)

(73) Assignee: NXP USA, Inc., Austin, TX (US)

(21) Appl. No.: 18/800,354

(22) Filed: Aug. 12, 2024

(30) Foreign Application Priority Data
Aug. 14, 2023 (EP) 23306374.2

(51) Int. Cl. H03F 1/02; H03F 1/56; H03F 3/24

(52) U.S. Cl. CPC H03F 1/0288; H03F 1/56; H03F 3/245; H03F 2200/451

(57) ABSTRACT

An amplifier device includes a first input terminal, a second input terminal, a first transistor having a first control electrode and first and second current-carrying electrodes, wherein the first control electrode is radio frequency (RF) coupled to the first input terminal and DC-coupled to a first bias network electrically coupled to the first control electrode, wherein the first bias network is configured to apply a first direct current (DC) bias to the first control electrode and is RF-isolated from the first control electrode. The amplifier device further includes a second transistor that includes a second control electrode that is RF coupled to the second input terminal and a second bias network electrically coupled to the second transistor, wherein the second bias network is configured to apply a second DC bias to the second transistor and is RF-isolated from the second transistor.

### CROSS-REFERENCE TO RELATED APPLICATIONS

This application claims priority under 35 U.S.C. § 119 to European patent application no. 23306374.2, filed Aug. 14, 2023, the contents of which are incorporated by reference herein.

### TECHNICAL FIELD

Embodiments of the subject matter described herein relate generally to RF amplifiers.

### BACKGROUND

High-efficiency radio-frequency (RF) amplifiers are increasingly finding use in communications applications. These high-efficiency RF amplifiers are desired because of the lower system size and cost achieved by the need for less cooling capability and because of the reduced energy needed to power these communications applications. Conventional high efficiency amplifiers (e.g., tuned class-AB) are operated at constant power supply voltages. Moreover, conventional high efficiency RF amplifiers are operated in a backed-off power condition. This backed-off power condition lowers amplifier efficiency.

Conventional high efficiency RF amplifiers may experience periods of low traffic conditions. This often means that the amplifiers have reduced efficiency because the amount of amplifier back off increases. This reduced efficiency results in excess energy usage. Thus, amplifier devices with improved efficiency are desired.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIGS. 1A and 1B are simplified schematic diagrams of an amplifier device in accordance with an example embodiment;

FIG. 2 is a graphical representation depicting operation of the amplifier device of FIGS. 1A and 1B;

FIG. 3 is a schematic diagram of an amplifier device in accordance with an embodiment;

FIG. 4 is a schematic diagram of an amplifier device in accordance with an embodiment;

FIG. 5A is a top-down, plan view of an apparatus and FIG. 5B is a cross-sectional side view along cutline 5B-5B of FIG. 5A, in accordance with an embodiment;

FIG. 6A is a top-down, plan view of an amplifier device in accordance with an embodiment and FIG. 6B is an isometric view of an amplifier device in accordance with an embodiment;

FIG. 7A is a top-down, plan view of an amplifier device in accordance with an embodiment and FIG. 7B is an isometric view of the amplifier device in accordance with an embodiment;

FIGS. 8A, 8B, 8C, and 8D are graphical representations depicting operation of the amplifier device of FIG. 5; and

FIGS. 9A, 9B, 9C, 9D, 9E, and 9F are graphical representations depicting operation of the amplifier device of FIG. 5 in comparison to a conventional amplifier device.

### SUMMARY

In one aspect, an amplifier device may include a first amplifier electrically coupled to a first input terminal and to a first output terminal, wherein the first amplifier may include a first transistor that includes a first control electrode, a first current-carrying electrode and a second current carrying electrode, configured to support a current flow between the first-current-carrying electrode and the second current-carrying electrode, wherein the first control electrode is configured to control the current flow between first current-carrying electrode and the second current-carrying electrode, wherein the first control electrode may be radio frequency (RF) coupled to the first input terminal, and wherein the first current-carrying electrode may be electrically coupled to the first output terminal, according to an embodiment. In an embodiment, a first bias network may be electrically coupled to the first control electrode, wherein the first bias network may be configured to apply a first direct current (DC) bias to the first control electrode and may be RF-isolated from the first control electrode. In an embodiment, the amplifier device may include a second transistor that includes a second control electrode, a third current-carrying electrode and a fourth current carrying electrode, configured to support a current flow between the third-current-carrying electrode and the fourth current-carrying electrode, wherein the second control electrode is configured to control the current flow between third current-carrying electrode and the fourth current-carrying electrode, wherein the second control electrode may be RF coupled to the first input terminal, wherein the third current-carrying electrode may be electrically coupled to the first output terminal. A second bias network may be electrically coupled to the second control electrode, wherein the second bias network may be configured to apply a second DC bias to the second control electrode and may be RF-isolated from the second control electrode, according to an embodiment.

The amplifier device may further include a second amplifier electrically coupled to a second input terminal and a second output terminal, wherein the second amplifier may include a third transistor that includes a third control electrode, a fifth current-carrying electrode and a sixth current carrying electrode, configured to support a current flow between the fifth-current-carrying electrode and the sixth current-carrying electrode, wherein the third control electrode is configured to control the current flow between fifth current-carrying electrode and the sixth current-carrying electrode, wherein the third control electrode may be RF coupled to the second input terminal, and wherein the fifth current-carrying electrode may be electrically coupled to the second output terminal, according to an embodiment. A third bias network may be electrically coupled to the third control electrode, wherein the third bias network may be configured to apply a third DC bias to the third control electrode and may be RF-isolated from the third control electrode, according to an embodiment. A fourth transistor that includes a fourth control electrode, a seventh current-carrying electrode and an eighth current carrying electrode, configured to support a current flow between the seventh-current-carrying electrode and the eighth current-carrying electrode, wherein the fourth control electrode is configured to control the current flow between seventh current-carrying electrode and the eighth current-carrying electrode, wherein the fourth control electrode may be radio frequency (RF) coupled to the second input terminal, and wherein the seventh current-carrying electrode may be electrically coupled to the second output terminal, according to an embodiment. In an embodiment, a fourth bias network may be electrically coupled to the fourth control electrode, wherein the fourth bias network may be configured to apply a fourth DC bias to the second control electrode and may be RF-isolated from the fourth control electrode.

In an embodiment, the amplifier device may also include a transmission line having a phase shift and may be configured to electrically couple the first output terminal and the second output terminal. An impedance transformer may be electrically coupled to a summing node at the element selected from the group consisting of the first output terminal and the second output terminal.

In an embodiment, the amplifier device may include a splitter device having a splitter input and a first splitter output and a second splitter output and configured to divide a signal delivered to the splitter input between the first splitter output and the second splitter output with a splitter phase difference between the first splitter output and the second splitter output, wherein a difference between the phase difference and the phase shift of the transmission line is less than twenty percent, wherein the first input terminal is electrically coupled to the first splitter output and the second input terminal is electrically coupled to the second splitter output.

In an embodiment, the first amplifier may be configured as a carrier amplifier and the second amplifier may be configured as a peaking amplifier.

In an embodiment, the first amplifier may be configured to operate in a first state and to operate in a second state, according to an embodiment. In an embodiment, when in the first state, the first transistor and the second transistor may be configured to operate with a first bias applied to the first bias network, a second bias applied to the second bias network, wherein the first bias and second bias allow an RF current of at least fifty percent of the maximum current of the second transistor may flow from the third current-carrying electrode to the fourth current-carrying element of the second transistor when the first transistor is operated at a saturated output power, and a third bias applied to the first current-carrying electrode and to the third current-carrying electrode, according to an embodiment. When operating in the second state, the first transistor and the second transistor may be configured to operate with the first bias applied to the first bias network, a fourth bias applied to the second bias network such that the fourth bias allows an RF current of less than ten percent of the maximum current of the second transistor flows through the second transistor when the first transistor is operated at a saturated output power, and a fifth bias applied to the first current-carrying electrode and to the third current-carrying electrode, according to an embodiment.

In an embodiment, the first transistor may be configured as a field effect transistor, wherein the first control terminal may be configured as a gate electrode, wherein the first current-carrying element may be configured as a drain electrode, and wherein the second current-carrying element may be configured as a source electrode.

An embodiment may include a first coupling element having a first terminal and a second terminal, wherein the second terminal may be electrically coupled to the first control electrode.

An embodiment may include a second coupling element having a third terminal and a fourth terminal, wherein the fourth terminal may be electrically coupled to the second control electrode, and wherein the first terminal may be electrically coupled to the third terminal.

A driver amplifier comprising a transistor may be electrically coupled to the first terminal of the first coupling element and to the third terminal of the second coupling element.

An embodiment may include a first input harmonic matching network, configured to provide a harmonic termination for the first transistor at a harmonic frequency and may also include a second harmonic matching network, configured to provide a harmonic termination for the second transistor at the harmonic frequency.

In another aspect, an embodiment may include a power amplifier device comprising a first amplifier electrically coupled to a first input terminal and to a first output terminal. The first amplifier may include a first field effect transistor that includes a first gate electrode, a first drain electrode and a first source electrode, configured to support a current flow between the first drain electrode and the first source electrode, wherein the first gate electrode may be configured to control the current flow between the first drain electrode and the first source electrode, wherein the gate electrode may be radio frequency (RF) coupled to the first input terminal, and wherein the first drain electrode may be electrically coupled to the first output terminal, according to an embodiment. In an embodiment, a first bias network may be electrically coupled to the first gate electrode, wherein the first bias network may be configured to apply a first direct current (DC) bias to the first gate electrode and may be RF-isolated from the first gate electrode. In an embodiment, a second field effect transistor may include a second gate electrode, a second drain electrode and a second source electrode, configured to support a current flow between the second drain electrode and the second source electrode, wherein the second gate electrode may be configured to control the current flow between the second drain electrode and the second source electrode, wherein the second gate electrode may be RF coupled to the first input terminal, wherein the second drain electrode may be electrically coupled to the first output terminal. A second bias network may be electrically coupled to the second gate electrode, wherein the second bias network may be configured to apply a second DC bias to the second gate electrode and may be RF-isolated from the second gate electrode, according to an embodiment.

In an embodiment, a first capacitor having a first terminal and a second terminal, may be electrically coupled to the first gate electrode by its second terminal. A second capacitor having a third terminal and a fourth terminal, wherein the fourth terminal may be electrically coupled to the second gate electrode, and wherein the first terminal may be electrically coupled to the third terminal, according to an embodiment. In an embodiment, a first input matching network may be electrically coupled to the first gate electrode and configured to provide an impedance match for the first field effect transistor at a fundamental frequency and a second input matching network, may be electrically coupled to the second gate electrode and configured to provide an impedance match for the second transistor at the fundamental frequency.

A second amplifier may be electrically coupled to a second input terminal and a second output terminal, according to an embodiment. In an embodiment, the second amplifier may include a third field effect transistor that includes a third gate electrode, a third drain electrode and a third source electrode, configured to support a current flow between the third drain electrode and the third source electrode, wherein the third gate electrode is configured to control the current flow between the third drain electrode and the third source electrode, wherein the third gate electrode may be RF coupled to the second input terminal, and wherein the third drain electrode may be electrically coupled to the second output terminal. A third bias network may be electrically coupled to the third gate electrode, wherein the third bias network may be configured to apply a third DC bias to the third gate electrode and may be RF-isolated from the third gate electrode. An embodiment may include a fourth field effect transistor that includes a fourth gate electrode, a fourth drain electrode and a fourth source electrode, configured to support a current flow between the fourth drain electrode and the fourth source electrode, wherein the fourth gate electrode is configured to control the current flow between the fourth drain electrode and the fourth source electrode, wherein the fourth gate electrode may be radio frequency (RF) coupled to the second input terminal, and wherein the fourth drain electrode may be electrically coupled to the second output terminal. A fourth bias network may be electrically coupled to the fourth gate electrode, wherein the fourth bias network may be configured to apply a fourth DC bias to the fourth gate electrode and may be RF-isolated from the fourth gate electrode, according to an embodiment. In an embodiment, a transmission line having a phase shift may be configured to electrically couple the first output terminal and the second output terminal. An impedance transformer may be electrically coupled to a summing node at one of the first output terminal and the second output terminal, according to an embodiment. In an embodiment, a splitter device having a splitter input and a first splitter output and a second splitter output and configured to divide a signal delivered to the splitter input between the first splitter output and the second splitter output with a splitter phase difference between the first splitter output and the second splitter output, wherein a difference between the splitter phase difference and the phase shift of the transmission line may be less than twenty percent, may be coupled to the first input terminal at the first splitter output and the second input terminal may be electrically coupled to the second splitter output. A first amplifier may be configured as a carrier amplifier and the second amplifier may be configured as a peaking amplifier in a Doherty amplifier configuration, according to an embodiment.

An embodiment may include a first input harmonic matching network, configured to provide a harmonic termination for the first transistor at a harmonic frequency and a second harmonic matching network, configured to provide a harmonic termination for the second transistor at the harmonic frequency.

A driver amplifier comprising a transistor may be electrically coupled to the first terminal of the first capacitor and to the third terminal of the second capacitor, according to an embodiment.

In another aspect, an embodiment may include an apparatus that includes a base substrate, a first amplifier die coupled to the base substrate and electrically coupled to a first input terminal and to a first output terminal. In an embodiment, the first amplifier die may include a first field effect transistor that may include a first gate electrode, a first drain electrode, and a first source electrode, configured to support a current flow between the first drain electrode and the first source electrode, wherein the first gate electrode is configured to control the current flow between the first drain electrode and the first source electrode, wherein the gate electrode may be radio frequency (RF) coupled to the first input terminal, and wherein the first drain electrode is electrically coupled to the first output terminal. A first bias network may be electrically coupled to the first gate electrode, wherein the first bias network may be configured to apply a first direct current (DC) bias to the first gate electrode and may be RF-isolated from the first gate electrode, according to an embodiment. In an embodiment, a second field effect transistor may include a second gate electrode, a second drain electrode, and a second source electrode, configured to support a current flow between the second drain electrode and the second source electrode, wherein the second gate electrode may be configured to control the current flow between the second drain electrode and the second source electrode, wherein the second gate electrode may be RF coupled to the first input terminal, wherein the second drain electrode may be electrically coupled to the first output terminal. A second bias network may be electrically coupled to the second gate electrode, wherein the second bias network may be configured to apply a second DC bias to the second gate electrode and may be RF-isolated from the second gate electrode, according to an embodiment. An embodiment may include a first capacitor having a first terminal and a second terminal, wherein the second terminal may be electrically coupled to the first gate electrode. An embodiment may include a second capacitor element having a third terminal and a fourth terminal, and wherein the fourth terminal may be electrically coupled to the second gate electrode, and wherein the first terminal may be electrically coupled to the third terminal. A first input matching network may be electrically coupled to the first gate electrode and configured to provide an impedance match for the first field effect transistor at a fundamental frequency and a second input matching network and may be configured to provide an impedance match for the second field effect transistor at the fundamental frequency, according to an embodiment.

In an embodiment, the first field effect transistor and the second field effect transistor may be integrally formed on a first substrate, and wherein the first capacitor and the second capacitor may be formed on the first substrate.

In an embodiment, the first field effect transistor and the second field effect transistor may be formed on a first substrate, and the first capacitor and the second capacitor may be formed on a second substrate.

An embodiment may include a driver amplifier comprising a transistor formed on the second substrate, wherein the driver amplifier may be electrically coupled to the first terminal of the first capacitor and may be coupled to the third terminal of the second capacitor. The first bias network may be formed on the second substrate and the second bias network may be formed on the second substrate, according to an embodiment.

In an embodiment, a second amplifier may be coupled to the base substrate and may be electrically coupled to a second input terminal and a second output terminal, wherein the second amplifier may include a third transistor that includes a third gate electrode, a third drain electrode and a third source electrode, configured to support a current flow between the third drain electrode and the third source electrode. The third gate electrode is configured to control the current flow between the third drain electrode and the third source electrode, wherein the third control electrode is RF coupled to the second input terminal, and wherein the third drain electrode may be electrically coupled to the second output terminal, according to an embodiment. In an embodiment, a third bias network may be electrically coupled to the third gate electrode, wherein the third bias network may be configured to apply a third DC bias to the third gate electrode and may be RF-isolated from the third gate electrode. A fourth transistor may include a fourth gate electrode, a fourth drain electrode and a fourth source electrode an is configured to support a current flow between the fourth drain electrode and the fourth source electrode, wherein the fourth gate electrode may be configured to control the current flow between the fourth drain electrode and the fourth source electrode, wherein the fourth gate electrode may be radio frequency (RF) coupled to the second input terminal, and wherein the fourth drain electrode may be electrically coupled to the second output terminal, according to an embodiment. In an embodiment, a fourth bias network may be electrically coupled to the fourth gate electrode, wherein the fourth bias network may be configured to apply a fourth DC bias to the fourth gate electrode and may be RF-isolated from the fourth gate electrode. A transmission line formed over the base substrate having a phase shift and may be configured to electrically couple the first output terminal and the second output terminal, according to an embodiment. An impedance transformer may be formed over the base substrate and may be electrically coupled to a summing node at one of the first output terminal and the second output terminal, according to an embodiment. In an embodiment, a splitter device may be formed over the base substrate having a splitter input and a first splitter output and a second splitter output and configured to divide a signal delivered to the splitter input between the first splitter output and the second splitter output with a splitter phase difference between the first splitter output and the second splitter output, wherein a difference between the phase difference and the phase shift of the transmission line is less than twenty percent, wherein the first input terminal may be electrically coupled to the first splitter output and the second input terminal is electrically coupled to the second splitter output. The first amplifier may be configured as a carrier amplifier and the second amplifier may be configured as a peaking amplifier in a Doherty amplifier configuration, according to an embodiment.

### DETAILED DESCRIPTION

The amplifier device embodiments provided herein may overcome some or all of the aforementioned issues with high-efficiency amplifiers. Specifically, the amplifier device embodiments described herein are configured to allow biasing of transistors within amplifier devices in deep class-C bias to effectively reduce the total size of the active transistors within the amplifier. Such biasing for reduced effective size of active transistors may be useful for increasing the efficiency of amplifier devices during times of low-power operation (e.g., during low traffic in a radio network).

The following detailed description is merely illustrative in nature and is not intended to limit the embodiments of the subject matter or the application and uses of such embodiments. As used herein, the words “exemplary” and “example” mean “serving as an example, instance, or illustration.” Any implementation described herein as exemplary, or an example is not necessarily to be construed as preferred or advantageous over other implementations. Furthermore, there is no intention to be bound by any expressed or implied theory presented in the preceding technical field, background, or the following detailed description.

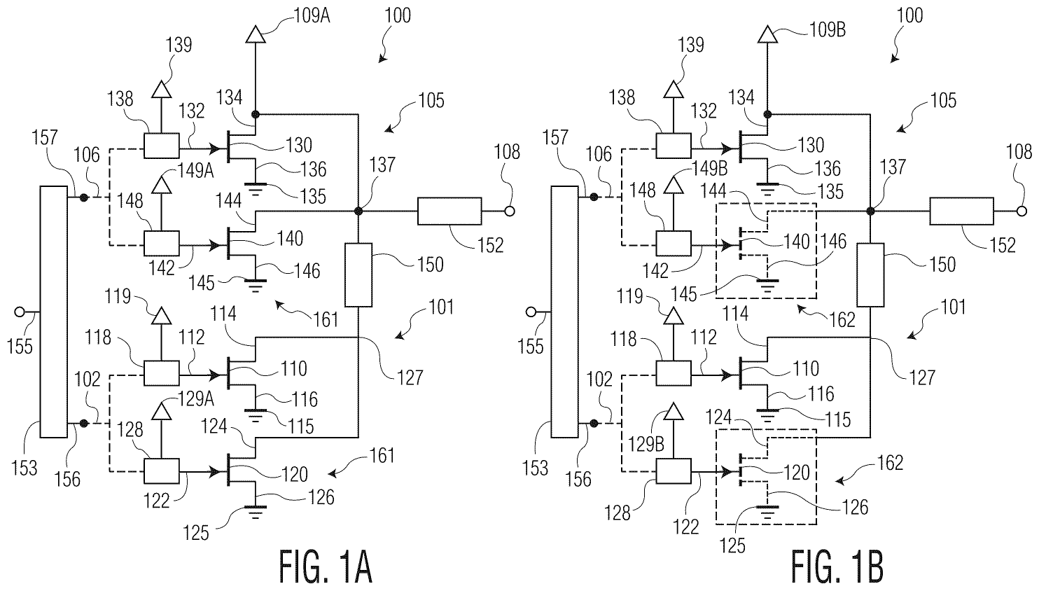

FIGS. 1A and 1B, collectively referred to as FIG. 1, are, respectively, simplified schematic diagrams of an amplifier device 100 in a high-power state 161 (i.e., “first state”) and a low-power state 162 (i.e., “second state”), in accordance with an example embodiment. In an embodiment an amplifier device 100 may include a first amplifier 101 electrically coupled to a first input terminal 102 and to a first output terminal 127.

According to an embodiment, first amplifier 101 may include a first field effect transistor 110 (i.e., “first transistor”) that may include a first gate electrode 112 (i.e., “first control electrode”), a first drain electrode 114 (i.e., “first current-carrying electrode”), and a first source electrode 116 (“i.e. second current-carrying electrode”), configured to support a current flow between the first drain electrode 114 and the first source electrode 116, wherein the first gate electrode 112 physically and electrically separates the first source electrode 116 and the first drain electrode 114 and may be configured to control current flow in a variable conductivity channel between the first drain electrode 114 and the first source electrode 116, wherein the gate electrode is radio frequency (RF) coupled to the first input terminal 102, and wherein the first drain electrode 114 is electrically coupled to the first output terminal 127. In an embodiment, the first source electrode 116 of first transistor 110 may be electrically coupled to ground potential 115.

In an embodiment, a first bias network 118 may be electrically coupled to the first gate electrode 112, wherein the first bias network 118 may be configured to apply a first direct current (DC) bias 119 (i.e., “first bias”) to the first gate electrode 112 and is RF-isolated from the first gate electrode 112. As used herein, the term “RF-isolated” means that radio-frequency (RF) coupling between two components that are RF-isolated is less than −20 dB, according to an embodiment. In other embodiments, RF coupling between two components that are RF-isolated is less than −10 dB, though higher or lower values may be used. In an embodiment, a second field effect transistor 120 (i.e., “second transistor”) that includes a second gate electrode 122 (i.e., “second control electrode”), a second drain electrode 124 (i.e., “third current-carrying electrode”), and a second source electrode 126 (i.e., “fourth current-carrying electrode”), may be configured to support a current flow between the second drain electrode 124 and the second source electrode 126, wherein the second gate electrode 122 may be configured to control the current flow between the second drain electrode 124 and the second source electrode 126, wherein the second gate electrode 122 may be RF coupled to the first input terminal 102, wherein the second drain electrode 124 may be electrically coupled to the first output terminal 127. A second bias network 128 may be electrically coupled to the second gate electrode 122, wherein the second bias network 128 may be configured to apply a second DC bias 129A/129B to the second gate electrode 122 and may be RF-isolated from the second gate electrode 122, according to an embodiment. In an embodiment, the source electrodes 126 of second transistor 120 may be electrically coupled to ground potential 125.

Still referring to FIG. 1, in an embodiment, the amplifier device 100 may include a second amplifier 105 electrically coupled to a second input terminal 106 and a second output terminal 137. The second amplifier 105 may include a third transistor 130 that may include a third gate electrode 132, a third drain electrode 134, and a third source electrode 136. The third transistor 130 may be configured to support a current flow between the third drain electrode 134 and the third source electrode 136, wherein the third gate electrode 132 may be configured to control current flow between the third drain electrode 134 and the third source electrode 136, wherein the third control electrode is RF coupled to the second input terminal 106, and wherein the third drain electrode 134 may be electrically coupled to the second output terminal 137, according to an embodiment. In an embodiment, a third bias network 138 may be electrically coupled to the third gate electrode 132, wherein the third bias network 138 may be configured to apply a third DC bias 139 to the third gate electrode and may be RF-isolated from the third gate electrode. In an embodiment, the source electrode 136 of third transistor 130 may be electrically coupled to ground potential 135.

In an embodiment, a fourth transistor 140 that includes a fourth gate electrode 142, a fourth drain electrode 144, and a fourth source electrode 146, may be configured to support a current flow between the fourth drain electrode 144 and the fourth source electrode 146, wherein the fourth gate electrode 142 may be configured to control the current flow between the fourth drain electrode 144 and the fourth source electrode 146, wherein the fourth gate electrode 142 may be radio frequency (RF) coupled to the second input terminal 106, and wherein the fourth drain electrode 144 may be electrically coupled to the second output terminal, according to an embodiment. A fourth bias network 148 electrically coupled to the fourth gate 142 electrode, wherein the fourth bias network 148 may be configured to apply fourth DC bias 149A/149B to the fourth gate electrode 142 and may RF-isolated from the fourth gate electrode 142. In an embodiment, the source electrode 146 of fourth transistor 140 may be electrically coupled to ground potential 145.

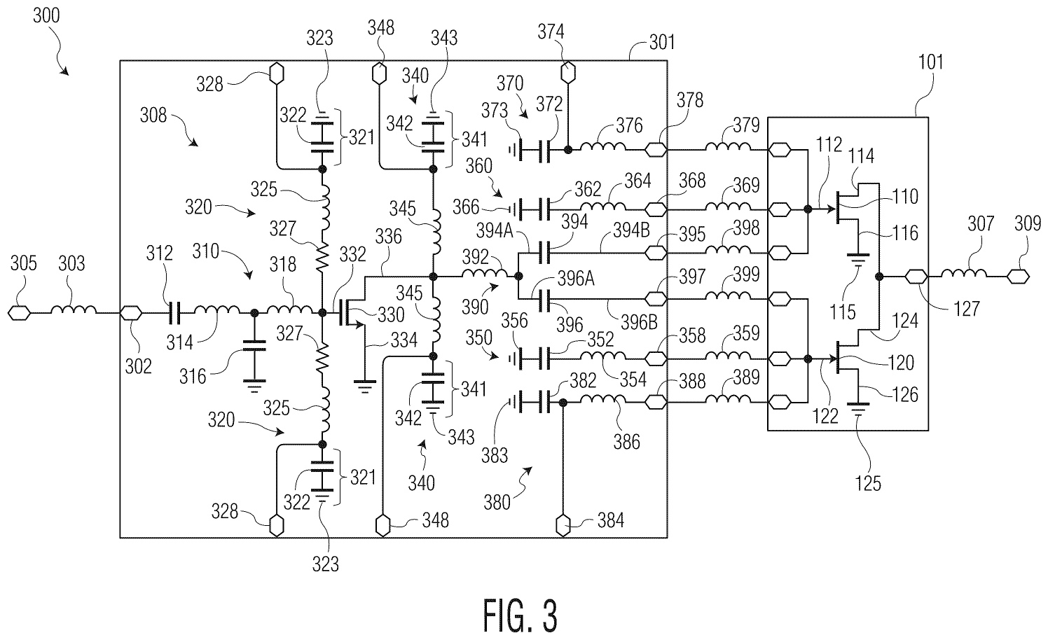

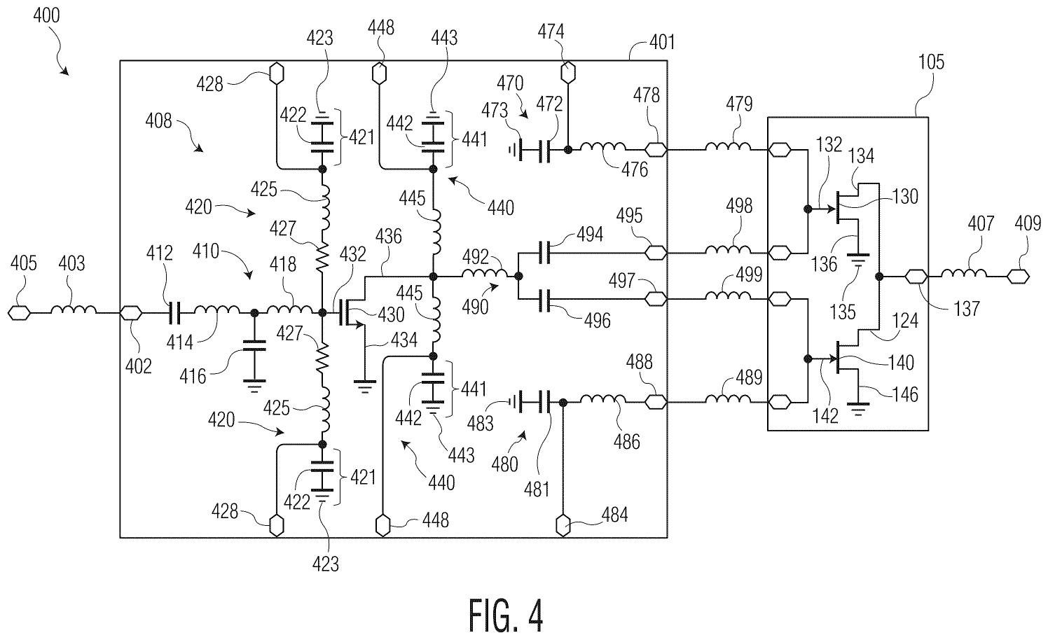

In an embodiment, the first, second, third, and fourth transistors 110, 120, 130, 140 may include field effect transistors (FET's) (such as heterojunction FET's (HFET's), metal-semiconductor FET's (MESFET's), or metal oxide semiconductor FET's (MOSFET's)), each of which include a gate (control terminal), a source (a first current-carrying terminal), and a drain (a second current-carrying terminal). For convenience of explanation and not for limitation, various embodiments of the invention will be illustrated using GaN HFET active devices for amplifier device 100 and silicon laterally diffused metal oxide semiconductor devices (LDMOS) devices for the driver amplifiers 308, 408 of FIGS. 3 and 4, which are preferred. However, many other active device types may also be employed and are intended to be included within the scope of the invention, as for example and not intended to be limiting, bipolar devices, junction field effect devices, various insulated gate field effect devices, and so forth. Alternatively, the first, second, third, and fourth transistors 110, 120, 130, and 140 may include a bipolar junction transistors (BJT) or a heterojunction BJT (HBT). Accordingly, references herein to a “gate,” “drain,” and “source,” are not intended to be limiting, as each of these designations has analogous features for a bipolar device implementation (e.g., a base, collector, and emitter, respectively).

In an embodiment, the first transistor 110 may have a total gate width of between about 0.5 and about 50 millimeters (mm) (e.g., about 1 mm), although higher or lower values of the total gate width may be used in some embodiments. In an embodiment, first, second, third, and fourth transistors 110, 120, 130, and 140 have an input capacitance (i.e., gate-source capacitance) between first, second, third, and fourth gate electrodes 112, 122, 132, and 142 and first, second, third, and fourth source electrodes 116, 126, 136, and 146 of the first, second, third, and fourth transistors 110, 120, 130, 140. In an example embodiment, the first, second, third, and fourth transistors 110, 120, 130, 140 have a gate source capacitance between about 0.5 pF per millimeter of gate periphery (pF/mm) and about 3.5 pF/mm (e.g., 2.5 pF/mm), though higher or lower values may be used. In an embodiment, the first second, third, and fourth transistors 110, 120, 130, and 140 have an output capacitance (i.e., drain-source capacitance) between first, second, third, and fourth drain terminals 114, 124, 134, 144 and first, second, third, and fourth source electrodes 116, 126, 136, and 146. In an embodiment, first. second, third, and fourth transistors 110, 120, 130, and 140 have a drain-source capacitance between about 0.2 pF per millimeter of gate periphery (pF/mm) and about 1 pF/mm (e.g., about 0.4 pF/mm), though other higher or lower values may be used.

In an embodiment, first and second amplifiers 101 and 105 may be combined in a Doherty configuration. To this end, a transmission line 150 may be used in conjunction with the output capacitances of first, second, third, and fourth transistors 110, 120, 130, and 140 to achieve a phase shift between the outputs 127 and 137 of first and second amplifiers 101 and 105. Transmission line 150 may be configured to electrically couple the first output terminal 127 and the second output terminal 137, according to an embodiment. In an embodiment, the phase shift may be between about 80 and 100 degrees. In an embodiment, the phase shift introduced in part by transmission line 150 may be added to phase shift arises from capacitive loading of the output capacitance of first, second, third and fourth transistors 110, 120, 130, and 140 as well as additional inductance coupled in series at one or more ends of the transmission line 150 (not shown). Thus, a transmission line phase shift due only to transmission line 150 may be less than the phase shift and may be to achieve the desired amount of phase shift. For example, the transmission line phase shift may be, e.g., 20 degrees to 50 degrees, but due to output capacitance of transistors 110, 120, 130, 140, and possibly additional capacitors and inductors (not shown), the phase shift may be approximately 90 degrees, e.g., 80 and 100 degrees. In other embodiments, the phase shift may have higher or lower values, e.g., 30 to 120 degrees, depending on the application. In an embodiment, an impedance transformer 152 may be electrically coupled to second output 137 that creates a summing node at second output 137 and to output terminal 108. As used herein, the term “summing node” refers to a point at which a peaking amplifier is electrically connected to a carrier or main amplifier in, e.g., a Doherty amplifier configuration.

In other embodiments, the summing node and connection to impedance transformer 152 may be at the first output terminal 127. In these embodiments, first amplifier 101 may be configured as a carrier amplifier and second amplifier 105 may be configured as a peaking amplifier. In these embodiments, transmission lines having phase shifts approximating the phase difference of the splitter (e.g., 90 degrees) may be added to the carrier amplifier path and to the peaking amplifier path (not shown). A splitter 153 having a splitter input 155, a first splitter output 156, and a second splitter output 157 may be configured to divide a signal delivered to the splitter input 155 between the first splitter output 156 and the second splitter output 157 with a splitter phase difference between the first splitter output 156 and the second splitter output 157, according to an embodiment. In an embodiment, the splitter phase difference may be between about 45 degrees and about 135 degrees. In an embodiment, a difference between the splitter phase difference and the phase shift associated with transmission line 150 and second splitter output 157 may be less than twenty percent of the splitter phase difference. In an embodiment, the first amplifier 101 may be configured as a carrier amplifier and the second amplifier 105 may be configured as a peaking amplifier in a Doherty amplifier configuration.

In an embodiment, the first and second amplifiers 101, 105 may be configured to operate in high power state 161 depicted in FIG. 1A and to operate in a low-power state 162 depicted FIG. 1B, according to an embodiment. In an embodiment, when operating in high-power state 161, the first and third transistors 110 and 130 and the second and fourth transistors 120 and 140 may be operated with first and third biases 119, 139 applied to the first and third bias networks 118, 138 and second and fourth biases 129A, 149A applied to the second and fourth bias networks 128, 148. During saturated operation of amplifier device 100, an RF current of an least fifty percent of the maximum current of the second and fourth transistors 120, 140 may flow from the second and fourth drain electrodes 124, 144 (i.e., “third and seventh current-carrying electrodes”) to the second and fourth source electrodes 126, 146 (i.e., “fourth and eighth current-carrying electrodes”) of the second and fourth transistors 120, 140 when the first and third transistors 110, 130 are operated at a saturated output power, and a fifth bias 109A is applied to the first, second, third, and fourth drain electrodes 114, 124, 134, 144, (i.e., “first, third, fifth, and seventh current-carrying electrodes”), according to an embodiment. When operating in the low-power state 162 of FIG. 1B, the first and third transistors 110, 130 and the second and fourth transistors 120, 140 may be operated with first and third biases 119, 139 applied to the first and third bias networks 118, 138 and second and fourth biases 129B, 149B applied to the second and fourth bias networks 128, 148 such that an RF current of less than ten percent of the maximum current of the second and fourth transistors 120, 140 flows through the second and fourth transistors 120, 140 when the first and third transistors 110, 130 are operated at a saturated output power, according to an embodiment. In other embodiments, and when operating in the low-power state 162 of FIG. 1B, the first and third transistors 110, 130 and the second and fourth transistors 120, 140 may be operated with first and third biases 119, 139 applied to the first and third bias networks 118, 138 and second and fourth biases 129B, 149B applied to the second and fourth bias networks 128, 148 such that an RF current of less than one percent of the maximum current of the second transistor flows through the second and fourth transistors 120, 140 when the first and third transistors 110, 130 are operated at a saturated output power, according to an embodiment. In an embodiment, a magnitude of a difference in the magnitude of a saturated efficiency in the high-power state 161 (i.e., “first state”) and an efficiency in the second state 162 may be less than twenty percent of the efficiency in the high-power state 161. According to an embodiment, a fifth bias 109B may be applied to the first, second, third, and fourth drain electrodes 114, 124, 134, 144, (i.e., “first, third, fifth, and seventh current-carrying electrodes”) when operating in the low-power state 162. In an embodiment, the fifth bias 109B may be a lower value (e.g., 28V) than the fifth bias 109A (e.g., 48V) when operating in the low-power state 162.

In an embodiment, amplifier device 100 may be operated in a transmitter system, wherein individual power supplies (not shown) may be used to supply first bias 119, second bias 129, third bias 139A/139B, fourth bias 149A/149B, and fifth bias 109A/109B. According to an embodiment, a bias controller (not shown) may be used to control the voltage levels provided for first bias 119, second bias 129A/129B, third bias 139, fourth bias 149A/149B, and fifth bias 109A/109B. In an embodiment, the bias controller may sense the traffic level in the amplifier system and, therefore, the output power required for amplifier device 100. As a result, the bias voltages applied to first and third biases 119, 139, second and fourth biases, 129A/129B, 149A/149B, and fifth bias 109A/109B, may be adjusted to optimize the efficiency of amplifier device 100.

For example, and in and in an embodiment, where first amplifier 101 is configured as a carrier amplifier and second amplifier 105 is configured as a peaking amplifier with first, second, third and fourth transistors 110, 120, 130, and 140 based on gallium nitride (GaN) transistor technology, the first, second, and fifth biases 119, 129A, 109A corresponding to high-power state 161 may include a gate voltage (e.g., gate bias of −2.5 V to −2.9V or approximately 0.1 to 0.5 V above a threshold voltage of −3V) that corresponds to a class A-B quiescent drain current bias, e.g., less than five percent of the full channel current of first transistor 110, and fifth bias 109A applied to the first, second, third, and fourth drain electrodes 114, 124, 134, 144 (e.g. a drain voltage of 48V) that corresponds to high-power operation, according to an embodiment. Likewise, the third and fourth biases 139, 149A of third and fourth transistors 130 and 140 of second amplifier 105 may include a gate voltage that corresponds to a class C bias, e.g., approximately zero current with a gate bias between approximately 0.1V and 2V below a threshold voltage (e.g. −3.1 V to −2V for −3V threshold voltage), while fifth bias 109A (e.g. 50V) is applied to drain electrodes 134, 144 of the third and fourth transistors 130, 140 according to an embodiment.

For example, and in an embodiment, where first amplifier 101 is configured as a carrier amplifier and second amplifier 105 is configured as a peaking amplifier with first, second, third and fourth transistors based on gallium nitride (GaN) transistor technology, the first bias 119 corresponding to low-power state 162 may include a gate voltage (e.g., gate bias of approximately −2.5 V to −2.9V or approximately 0.1 to 0.5 V above a threshold voltage of −3V) that corresponds to a class A-B bias, e.g., a quiescent drain current less than ten percent of the full channel current of first transistor 110, according to an embodiment. Likewise, the third bias 139 applied to third transistor 130 of second amplifier 105 may include a gate voltage that corresponds to a class C bias for transistor 130 (e.g., approximately zero current with a gate bias between approximately 0.1V and 1V below a threshold voltage (e.g. −3.1 V to −4V for −3V threshold voltage).The second and fourth biases 129B, 149B applied to the second and fourth bias networks 128, 148 may correspond to a deep class C condition (e.g., a gate bias of −8V, approximately 5V below the threshold voltage of approximately −3V) for second and fourth transistors 120, 140. Likewise, the fifth bias 109B applied to the first, second, third, fourth drain electrodes 114, 124, 134, 144 (e.g., a drain voltage of 28V) corresponds to low-power operation, according to an embodiment. In low-power state 162, the effect of the third and fourth biases 129B and 149B biasing transistors 120, 140 in deep class C may have the effect to reduce the overall effective gate periphery of first amplifier 101 and second amplifier 105 since the devices are operated in deep depletion and do not contribute current to the operation of amplifier device 100, according to an embodiment.

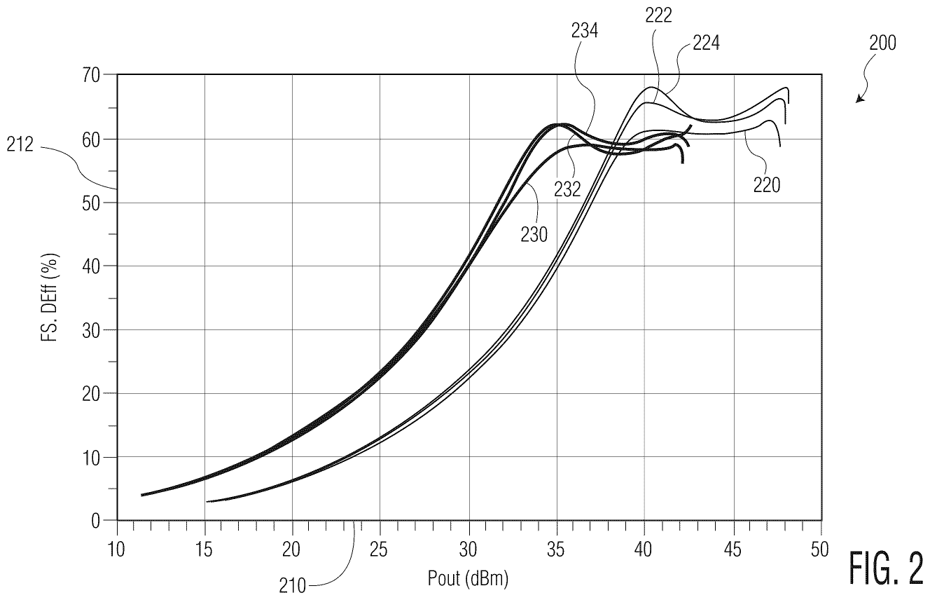

FIG. 2 is a graphical representation 200 depicting operation of the amplifier device 100 of FIGS. 1A and 1B in high and low-power states 161, 162, according to an embodiment. Referring simultaneously to FIGS. 1A, 1B, and FIG. 2, graphical representation 200 shows simulated drain efficiency 212 versus output power 210. Traces 220, 222, 224 represent efficiency versus output power at frequencies of 2.5 gigahertz (GHz), 2.6 GHz, and 2.7 GHz, respectively when amplifier device 100 is operated in high-power state 161. Traces 230, 232, 234 represent efficiency versus output power at frequencies of 2.5 GHz, 2.7 GHz, and 2.6 GHz, respectively when amplifier device 100 is operated in low-power state 162. In this example, first and second transistors 110 and 120 have total gate widths (i.e., unit gate width times the number of fingers) of 1 millimeter (mm) each while third and fourth transistors 130 and 140 have total gate widths of 1.75 mm each. Traces 220, 222, 224 show that during the high-power state 161 where first and second biases 119, 129A are set to achieve 8.5 mA/mm at a drain voltage of 48V is applied to first and second transistors 110, 120 and a class C bias of −3.9V with a drain bias of 48V is applied to the third and fourth transistors 130, 140, an efficiency of greater than 60% may be achieved over the power range of 40 dBm to 47 dBm, according to an embodiment. Traces 230, 232, 234 show that during the low-power state 162 where first bias 119 is set to achieve 8.5 mA/mm at a drain voltage of 28V is applied to first transistor 110, third bias 139 is set to a class C bias of −3.9V with a drain bias of 28V is applied to third transistor 130, and a deep class C bias of −8V is applied to second and fourth biases 129B and 149B to bias the second and fourth transistors 120, 140 to deep class C, an efficiency of greater than 58% over the power range of 35 to 42 dBm may be achieved, according to an embodiment. Thus, the dynamic range of the amplifier device 100 for achieving greater than 58% efficiency may be extended from about 8 dB to about 14 dB, according to an embodiment.

FIG. 3 is a schematic diagram of first power amplifier device 300 in accordance with an embodiment. First power amplifier device 300 (i.e., “first amplifier”) may include a first amplifier 101 electrically coupled to a first input terminal 302 and to a first output terminal 127 and driver and bias circuitry 301 coupled the first amplifier 101. The first amplifier 101 may include a first field effect transistor 110 that includes a first gate electrode 112, a first drain electrode 114, and a first source electrode 116. First field effect transistor 110 may be configured to support a current flow between the first drain electrode 114 and the first source 116 electrode, wherein the first gate electrode 112 may be configured to control the current flow between the first drain electrode 114 and the first source electrode 116, wherein the gate electrode 112 may be RF-coupled to the first external input terminal 305, and wherein the first drain electrode 114 may be electrically coupled to the first output terminal 127 and to first external output terminal 309 via output wire bond 307, according to an embodiment. In an embodiment, a first bias network 370 that includes RF bypass capacitor 372 coupled to ground 373 and inductor 376 that may be electrically coupled to the first gate electrode 112 and may be configured to apply a first direct current (DC) bias via terminal 374, inductor 376, terminal 378, bond wire 379, and wherein the first bias network 370 to the first gate electrode 112 and may be RF-isolated from the first gate electrode 112. In an embodiment, RF bypass capacitor 372 may have a value between about 5 picofarads and about 100 picofarads, although other higher or lower values may be used. Inductor 376 may have a value of between about 5 nanohenries and about 100 nanohenries although other higher or lower values may be used, according to an embodiment.

In an embodiment, a second field effect transistor 120 may include a second gate electrode 122, a second drain electrode 124, and a second source electrode 126, configured to support a current flow between the second drain electrode 124 and the second source electrode 126, wherein the second gate electrode 122 may be configured to control the current flow between the second drain electrode 124 and the second source electrode 126, wherein the second gate electrode 122 may be RF-coupled to the first input terminal 302, wherein the second drain electrode 124 may be electrically coupled to the first output terminal 127. A second bias network 380 that includes RF bypass capacitor 382 coupled to ground 383 and inductor 386 may be electrically coupled to the first gate electrode through inductor 386, may be electrically coupled to the second gate electrode 122, wherein the second bias network 380 may be configured to apply a second DC bias to the second gate electrode 122 through terminal 384, inductor 386, terminal 388, and bond wire 389 and may be RF-isolated from the second gate electrode 122, according to an embodiment. In an embodiment, the values of components of second bias network 380 (e.g., RF bypass capacitor 382 and inductor 386) may be analogous to those of first bias network 370.

In an embodiment, circuitry 390 that includes a first capacitor 394 (i.e., “first coupling element”) having a first terminal 394A and a second terminal 394B, may be electrically coupled to the first gate electrode 112 through terminal 395 and bond wire 398 by its second terminal 394B. A second capacitor 396 (i.e., “second coupling element”) having a third terminal 396A and a fourth terminal 396B, may be electrically coupled by terminal 397 via the fourth terminal 396B and bond wire 399 to the second gate electrode 122. The first terminal 394A may be electrically coupled to the third terminal 396A, according to an embodiment. In an embodiment, a first input matching network that may include bond wires 369, 379, and 398 may be electrically coupled to the first gate electrode 112 through terminals 368, 378, 395 and may be configured to provide an impedance match for the first transistor 110 at a fundamental frequency. A second input matching network that may include bond wires 359, 389, and 399 may be electrically coupled to the second gate electrode 122 and may be configured to provide an impedance match for the second transistor 120 at the fundamental frequency.

An embodiment may include first and input harmonic matching networks 350, 360 that includes capacitors 352, 362 and inductors 354, 364 connected in series and electrically coupled to grounds 356, 366 and may be configured to provide a harmonic termination for the first transistor 110 at a harmonic frequency. An embodiment may also include input harmonic matching networks 350, 360 that may include capacitors 352, 362 and inductors 354, 364 connected in series and electrically coupled to ground 356, 366 and to terminals 358, 368 and is configured to provide a harmonic termination for the first and second transistors 110, 120 at the harmonic frequency. In an embodiment, capacitors 352, 362 may have values between about 0.3 picofarads and about 5 picofarads, although other higher or lower values may be used. Inductors 354, 364 may have values of between about 0.3 nanohenries and about 2 nanohenries although other higher or lower values may be used, according to an embodiment.

A driver amplifier 308 may be electrically coupled to the first terminal 394A of the first capacitor and the third terminal 396A of the second capacitor and may be RF-coupled to first input terminal 302 through series capacitor 312 and from first input terminal 302 to first external input terminal 305. Transistor 330 is the primary active device of driver amplifier 308 and includes a gate electrode 332, source terminal 334, and drain electrode 336. In an embodiment, driver amplifier 308 may be coupled to first external input terminal 305 through bond wire 303 and may include an input matching network 310 coupled to the gate electrode 332 of transistor 330, input bias networks 320 coupled to the gate electrode 332 and driver drain bias networks 340 coupled to the drain electrode 336 of the transistor 330. Driver amplifier 308 may be coupled to first and second capacitors 394 and 396 through inductor 392 which may be configured to provide impedance matching, according to an embodiment.

In an embodiment, input matching network 310 may include a “T” network that includes input match inductors 314, 318 that are electrically coupled together in series at a point coupled to ground by input match capacitor 316. Input match inductors 314, 318 may have values between about 0.1 nanohenries and about 5 nanohenries, according to an embodiment. Input match capacitor may have a value of between about 0.5 picofarads and about 2 picofarads, according to an embodiment. In an embodiment, input bias network 320 may include DC block 321 that includes RF bypass capacitor 322 and DC ground 323 may be electrically coupled to the gate electrode 332 through inductor 325 and resistor 327, wherein the input bias networks 320 may be configured to apply a first direct current (DC) bias to the gate electrode 332. In an embodiment, RF bypass capacitor 322 may have a value between about 2 picofarads and about 50 picofarads, although other higher or lower values may be used. Inductor 325 may have a value of between about 5 nanohenries and about 100 nanohenries although other higher or lower values may be used, according to an embodiment. Resistor 327 may have a value between about 1 ohm and about 1000 ohms, according to an embodiment. Terminal 328 is used to provide a connection of the input bias network to the DC gate bias. In an embodiment, driver drain bias networks 340 may include DC block 341 that includes RF bypass capacitor 342 and RF grounds 343 and may be electrically coupled to the drain electrode 336 through inductor 345, wherein the driver drain bias networks 340 may be configured to apply a first direct current (DC) bias to the drain electrode 336 through terminal 348. In an embodiment, RF bypass capacitor 342 may have a value between about 2 picofarads and about 50 picofarads, although other higher or lower values may be used. Inductor 345 may have a value of between about 5 nanohenries and about 100 nanohenries although other higher or lower values may be used, according to an embodiment.

FIG. 4 is a schematic diagram of a second power amplifier device 400 (i.e., “second amplifier”) in accordance with an embodiment. Second power amplifier device 400 may include a second amplifier 105 and driver and bias circuitry 401 that may be electrically coupled to a second input terminal 402 and a second output terminal 137, according to an embodiment. In an embodiment, the second amplifier 105 may include a third transistor 130 that includes a third gate electrode 132, a third drain electrode 134 and a third source electrode 136, wherein the third gate electrode 132 may be RF coupled to the second input terminal, and wherein the third drain electrode may be electrically coupled to the second output terminal. A third bias network 470 that includes blocking capacitor 472, ground 473, and inductor 476 may be electrically coupled to the third gate electrode 132, wherein the third bias network 470 may be configured to apply a third DC bias to the third gate electrode 132 and may be RF-isolated from the third gate electrode 132. An embodiment may include a fourth transistor 140 that includes a fourth gate electrode 142, a fourth drain electrode 144, and a fourth source electrode 146, configured to support a current flow between the fourth drain electrode 144 and the fourth source electrode 146, wherein the fourth gate electrode 142 is configured to control the current flow between the fourth drain electrode 144 and the fourth source electrode 146, wherein the fourth gate electrode 142 may be radio frequency (RF) coupled to the second input terminal, and wherein the fourth drain electrode 144 may be electrically coupled to the second output terminal 137. A fourth bias network 480 that includes DC block 481, ground 483, and inductor 486 may be electrically coupled to the fourth gate electrode 142, wherein the fourth bias network 480 may be configured to apply a fourth DC bias applied at terminal 484 to the fourth gate electrode 142 through terminal 488 and may be RF-isolated from the fourth gate electrode 142, according to an embodiment.

In an embodiment, other components included in second power amplifier device 400, (e.g. second external input terminal 405, bond wire 403, second input terminal 402, bond wire 407, driver amplifier 408, output terminal 409, input matching network 410, input match inductors 414, 418, input match capacitor 416, input bias networks 420, DC block 421, RF bypass capacitor 422, DC ground 423, inductor 425, resistor 427, driver terminals 428, 448, transistor 430, transistor gate electrode 432, transistor drain electrode 436, transistor source electrode 434, output bias networks 440, DC block 441, RF bypass capacitor 442, RF ground 443, inductor 445, series capacitor 412, coupling circuitry 490, inductor 492, first capacitor 494, second capacitor 496, bond wires 479, 489, 498, 499) have been described in connection with first power amplifier device 300 in FIG. 3.

In this example embodiment, second power amplifier device 400 does not include input harmonic termination networks as are included in first power amplifier device 300 of FIG. 3 (e.g., input harmonic termination networks 350, 360). In other embodiments, harmonic termination circuitry may be included in second power amplifier device 400 (not shown).

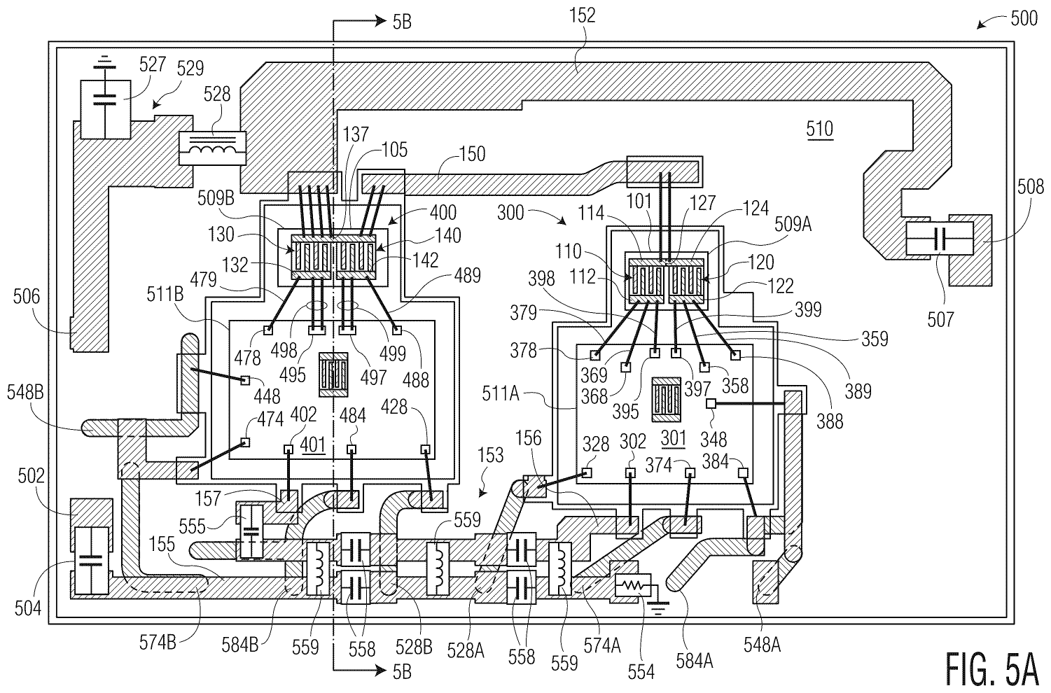

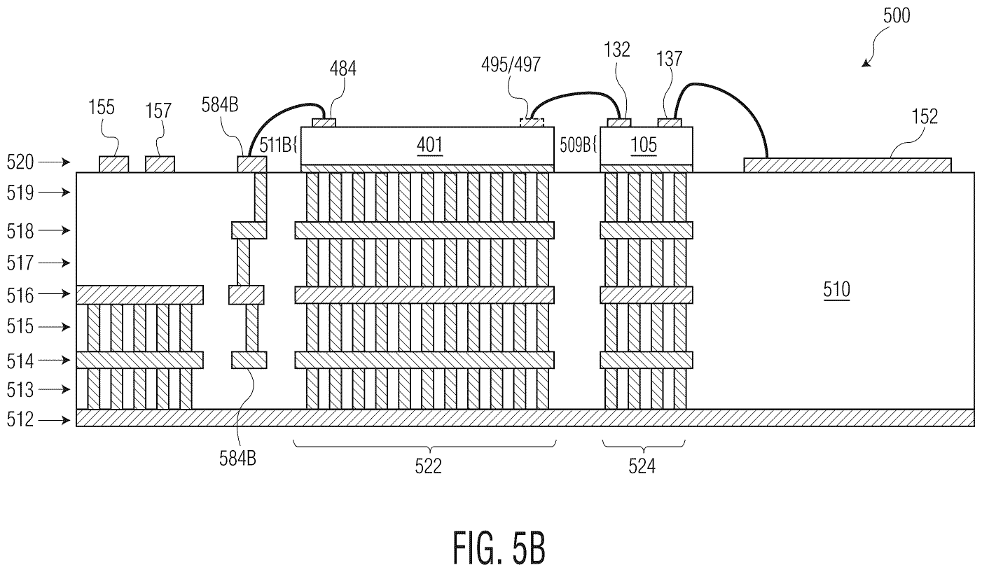

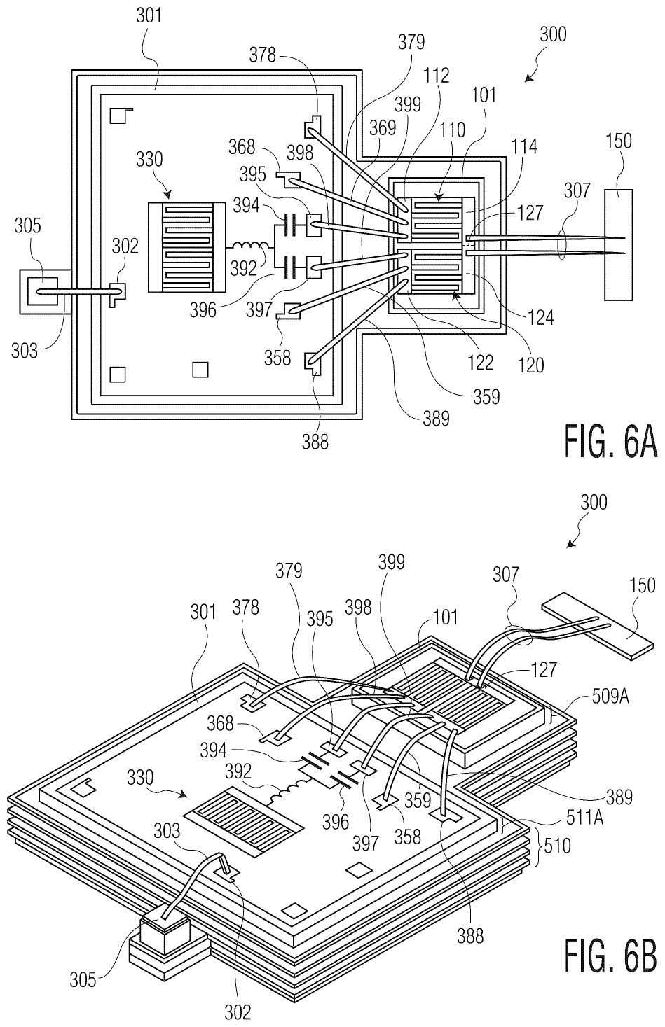

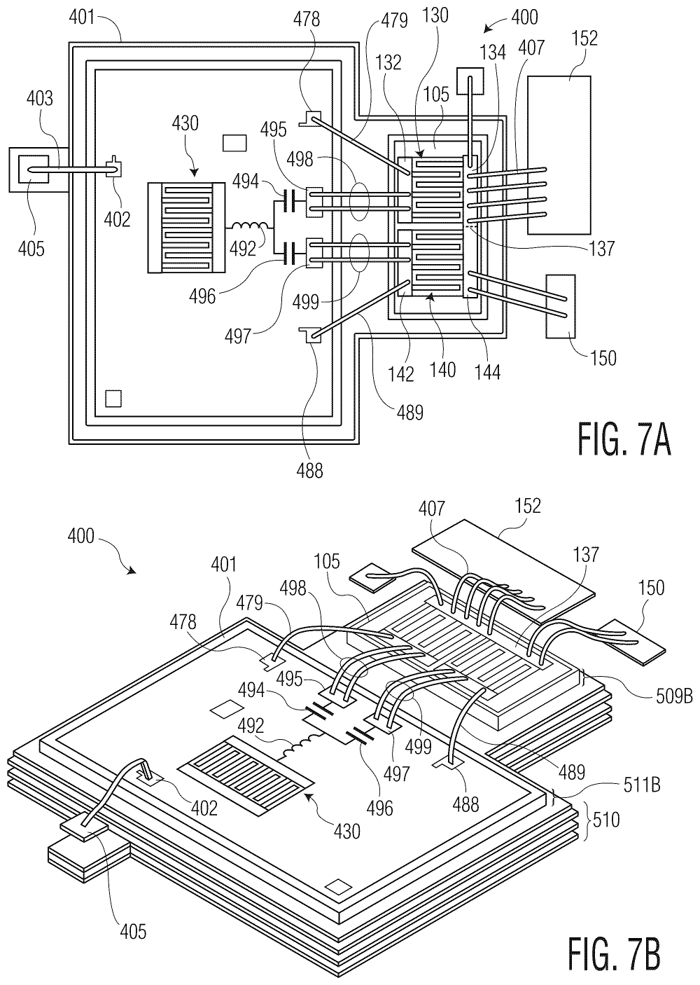

FIG. 5A is a top-down, plan view of an apparatus 500 and FIG. 5B is a cross-sectional side view along cutline 5B-5B of FIG. 5A, in accordance with an embodiment. FIGS. 6A, 6B, 7A, and 7B are top-down plan and isometric view of portions of apparatus 500 in accordance with an embodiment. The features of apparatus 500 may be best understood by viewing FIGS. 5A, 5B, 6A, 6B, 7A, and 7B simultaneously.

Apparatus 500 may include a base substrate 510, a first power amplifier device 300 coupled to the base substrate 510 and electrically coupled to a first input terminal 302 through driver and bias circuitry 301 and to a first output terminal 127. In an embodiment, the first amplifier 101 may include a first field effect transistor 110 that may include a first gate electrode 112, a first drain electrode 114, and a first source electrode 116 (not shown). A first bias network 370 (within driver and bias circuitry 301, not shown) may be electrically coupled to the first gate electrode 112 through bond wire 379, terminal 378, first bias network 370 (shown in FIG. 3), and may be configured to apply a first direct current (DC) bias to the first gate electrode 112 through terminal 374 from module terminal 574A, and may be RF-isolated from the first gate electrode, according to an embodiment. In an embodiment, a second field effect transistor 120 integrally formed with the first field effect transistor 110 may include a second gate electrode 122, a second drain electrode 124, and a second source electrode 126 (not shown). In an embodiment, the second gate electrode 122 may be RF-coupled to the first input terminal 302, wherein the second drain electrode 124 may be electrically coupled to the first output terminal. A second bias network 380 (shown within driver and bias circuitry 301 of FIG. 3) may be electrically coupled to the second gate electrode 122 through bond wire 389, terminal 388, wherein the second bias network 380 may be configured to apply a second DC bias provided through terminal 384 from module terminal 584A to the second gate electrode 122 and may be RF-isolated from the second gate electrode 122, according to an embodiment.

In an embodiment, a second power amplifier device 400 may be coupled to the base substrate 510 and may be electrically coupled to a second input terminal 402 and a second output terminal 137, wherein the second power amplifier device 400 may include a third transistor 130 that includes a third gate electrode 132, a third drain electrode 134, and a third source electrode 136 (not shown), configured to support a current flow between the third drain electrode 134 and the third source electrode 136 (see FIGS. 4 and 7A). In an embodiment, a third bias network 470 (within driver and bias circuitry 401, not shown) may be electrically coupled to the third gate electrode 132 through terminal 478 and bond wire 479, wherein the third bias network 470 may be configured to apply a third DC bias provided to terminal 474 from module terminal 574B to the third gate electrode 132 and may be RF-isolated from the third gate electrode 132. A fourth transistor 140 may include a fourth gate electrode 142, a fourth drain electrode 144, and a fourth source electrode 146 (not shown) and is configured to support a current flow between the fourth drain electrode 144 and the fourth source electrode 146, wherein the fourth gate electrode 142 may be configured to control the current flow between the fourth drain electrode 144 and the fourth source electrode 146, wherein the fourth gate electrode 142 may be radio frequency (RF) coupled to the second input terminal 402 (through driver and bias circuitry 401), and wherein the fourth drain electrode 144 may be electrically coupled to the second output terminal 137, according to an embodiment (see FIGS. 4 and 7A). In an embodiment, a fourth bias network 480 may be electrically coupled to the fourth gate electrode 142 through terminal 488 and bond wire 489, wherein the fourth bias network may be configured to apply a fourth DC bias through terminal 484 to module terminal 584B to the fourth gate electrode 142 and may be RF-isolated from the fourth gate electrode 142. Transmission line 150 formed over base substrate 510 may be configured to electrically couple the first output terminal 127 and the second output terminal 137, according to an embodiment. An impedance transformer 152 may be formed over the base substrate 510 and may be electrically coupled to a summing node at one of the first output terminal 127 and the second output terminal 137, according to an embodiment. Module drain terminal 506 may be coupled to impedance transformer 152 through bias network 529 that includes RF choke 528 and bypass capacitor 527, according to an embodiment. In the embodiment shown here, the summing node is at the second output terminal 137. Output terminal 508 may be coupled to impedance transformer 152 using coupling capacitor 507.

In an embodiment, the first transistor 110 and the second transistor 120 may be integrally formed on a first substrate 509A, and the first capacitor 394 and the second capacitor 396 may be formed on a second substrate 511A, with terminals 395, 397 as part of driver and bias circuitry 301. In other embodiments, the first transistor 110 and the second transistor 120 may be formed on first substrate 509A, and the first capacitor and the second capacitor may be formed on the first substrate 509A (not shown). Analogously, and in an embodiment, the third transistor 130 and the fourth transistor 140 may be integrally formed on a third substrate 509B, and the first capacitor 494 and the second capacitor 496 may be formed on a fourth substrate 511B with terminals 495, 497, respectively, and as part of driver and bias circuitry 401.

An embodiment may include driver and bias circuitry 301, 401 that includes transistors 330, 430 formed on the third and fourth substrates 509B, 511B wherein the driver amplifier may be electrically coupled to the first terminal of the first capacitor and may be coupled to the third terminal of the second capacitor. The first bias network 370 and the second bias network 380 may be formed on the second substrate 511A, according to an embodiment. The third bias network 470 and the fourth bias network 480 may be formed on the fourth substrate 511B, according to an embodiment. Terminals 328, 348 and 428, 448 that provide biasing to transistors 330 and 430 may be coupled to module terminals 528A, 548A and 528B, and 548B, respectively for connections to external power supplies.

In an embodiment, a splitter 153 may be formed over the base substrate 510 having a splitter input 155 and a first splitter output 156 and a second splitter output 157 and configured to divide a signal delivered to the splitter input 155 between the first splitter output 156 and the second splitter output 157 with a splitter phase difference between the first splitter output and the second splitter output, wherein a difference between the splitter phase difference and the phase shift associated with transmission line 150 is less than twenty percent, wherein the first input terminal 102 may be electrically coupled to the first splitter output 156 and the second input terminal 106 is electrically coupled to the second splitter output 157. Expressing this differently, the phase shift of the transmission line 150 may approximate the splitter phase difference such that their difference is less than about twenty percent. As used herein, the “phase shift of [a] transmission line” means the phase shift encountered by a signal and includes the effect of the phase shift of the transmission line and any loading of the transmission line by other circuit components (e.g., capacitances and inductances). Thus, in an embodiment, the phase shift of the transmission line 150 also includes the effect of output capacitances of third transistor 130 and fourth transistor 140 and/or additional matching elements (not shown) seen at output terminal 137. The first power amplifier device 300 may be configured as a carrier amplifier and the second power amplifier device 400 may be configured as a peaking amplifier in a Doherty amplifier configuration, according to an embodiment. In an embodiment, splitter 153 may be realized using a compact hybrid coupler wherein branches of the compact hybrid coupler are realized in a compact form-factor using lumped element capacitors 558, inductors 559, and termination resistor 554. A coupling capacitor 555 may RF couple second splitter output 157 to the second power amplifier device 400. In other embodiments, the splitter 153 may be realized using a branch line coupler. In other embodiments, the splitter 153 may be realized using a Lange coupler. In still other embodiments, the splitter 153 may be realized using a Wilkinson power divider with and extra transmission line length used to achieve a phase difference between the first splitter output 156 and the second splitter output 157. Splitter input 155 may be coupled to module input 502 with coupling capacitor 504.

Referring to FIGS. 5A and 5B, base substrate 510 may include a multi-layer structure that includes a first ground plane layer 512, a first metal layer 514, a second ground plane layer 516, a second metal layer 518, and third metal layer 520, according to an embodiment. In an embodiment, first vias 513 may connect first ground plane layer to first metal layer 514. Second vias 515 may connect first metal layer 514 to second ground plane layer 516, according to an embodiment. In an embodiment, third vias 517 may connect second ground plane layer 516 to second metal layer 518. Fourth vias 519 may connect second metal layer 518 to third metal layer 520, according to an embodiment. By stacking first ground plane layer 512, first metal layer 514, second ground plane layer 516, second metal layer 518, and third metal layer 520 using first, second, third, and fourth vias 513, 515, 517, and 519, heatsink regions 522 and 524 may be created under driver and bias circuitry 301 and first amplifier 101, according to an embodiment. In an embodiment, first ground plane layer 512 may be used to realize microstrip lines (e.g., transmission line 150) in conjunction with third metal layer 520. Second ground plane 516 layer may be used in conjunction with third metal layer 520 to realize transmission lines of narrower width (e.g., splitter input 155 and second output 157).

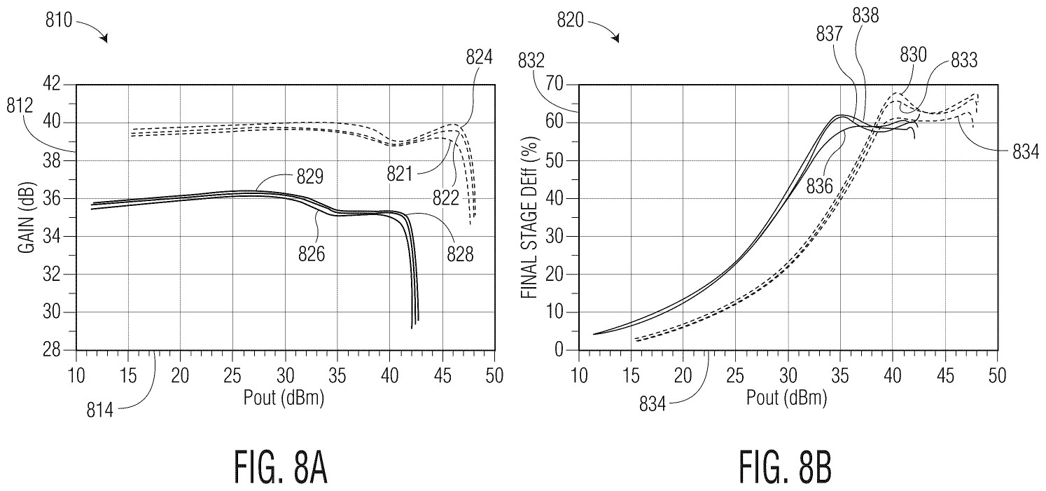

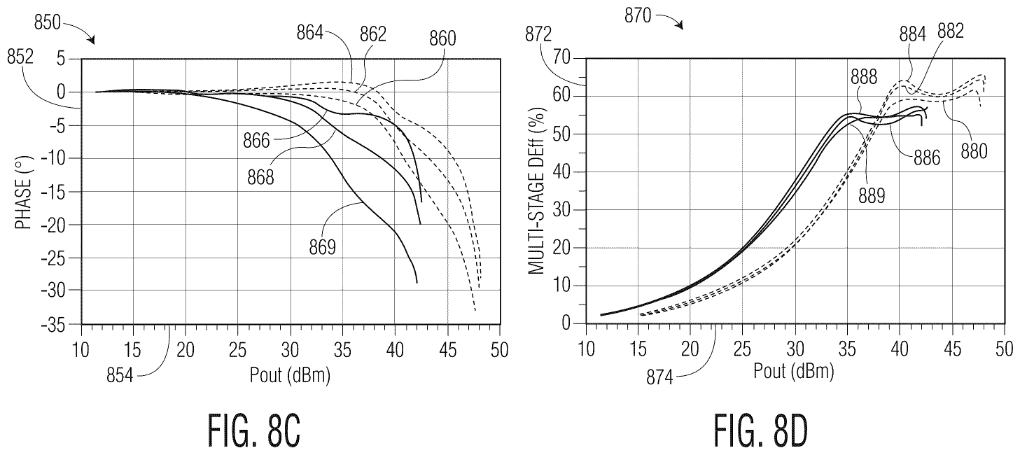

FIGS. 8A, 8B, 8C, and 8D, referred to collectively as FIG. 8, are graphical representations 810, 820, 850, 870 depicting simulated operation of the apparatus 500 of FIG. 5. According to an embodiment, graphs 810, 820, 850, 870 depict gain 812, final stage efficiency 832, insertion phase 852, and multi-stage efficiency 872 versus average output power 814, 834, 854, 874 for apparatus 500. Traces 821, 822, 824, 830, 833, 834, 860, 862, 864, 880, 882, 884, depict gain, efficiency, normalized insertion phase, and multi-stage efficiency of performance in a high-power mode. Trios of traces 821-824, 830-834, 860-864, 880-884 represent performance at 2.5, 2.6, and 2.7 GHz, respectively. In the high-power mode, bias conditions include a 48V bias applied to drain terminals 114, 124, 134, 144 of first and second power amplifier devices 300 and 400 with a quiescent current (I_{DQ}) of 18 mA evenly divided between first and second transistors 110, 120 for the first power amplifier device 300 and a gate bias of −3.9V applied to third and fourth gate terminals 132, 142, of third and fourth transistors 130, 140, according to an embodiment. In an embodiment, traces 826, 828, 829, 836, 837, 838, 866, 868, 869, 886, 888, 889 depict gain, efficiency, insertion phase, and multi-stage efficiency versus average output power for apparatus 500 in a low-power mode. Trios of traces 826-829, 836-838, 866-869, 886-889 represent 2.5, 2.6, and 2.7 GHz, respectively. In the low-power mode, bias conditions include a 28V bias applied to drain terminals 114, 124, 134, 144 of first and second power amplifier devices 300 and 400 with a quiescent current (I_{DQ}) of 8.5 mA for first transistor 110, 0 mA for second transistor 120 due to a gate bias of −8V applied to second gate 122 through second bias network 380 for the first power amplifier device 300 and a gate bias of −3.9V applied to third gate terminal 132 of third transistor 130, and a gate bias of −8V applied to gate of fourth transistor 140, according to an embodiment. Because second and fourth transistors are biased in deep class C, they are effectively “off” while first and third transistors operate in class AB and class C, according to an embodiment.

In FIG. 8A, graph 810 shows transducer gain (G_{T}) expressed in dB versus output power in decibels with respect to 1 milliwatt (dBm). Traces 826-829 corresponding to low-power operation with first and third transistors 110 and 130 biased in class AB and class C, respectively, both at 28V drain voltage and second and fourth transistors 120 and 140 biased off, also at 28V drain voltage, show approximately 3 dB less gain from 15 to 40 dBm output power than traces 820-824 corresponding to first and second transistors 110, 120 biased in class AB, third, and fourth transistors 130, 140, biased in class C, all operating in the high-power state, all with 48V drain voltage.

In FIG. 8B, graph 820 shows final stage drain efficiency in percent, versus output power in dBm. At an output power of 35 dBm, traces 830-839 corresponding to low-power operation with first and third transistors 110 and 130 biased in class AB and class C, respectively, both at 28V drain voltage and second and fourth transistors 120 and 140 biased off, also at 28V drain voltage show approximately 20 percentage points higher efficiency than traces 830-839 corresponding to first and second transistors 110, 120 biased in class AB and third and fourth transistors 130, 140, biased class C in the high-power state all biased with a 48V drain voltage.

In FIG. 8C, graph 850 shows insertion phase distortion in degrees in response to amplitude modulation (AM-PM) versus output power in dBm. Traces 866-869 corresponding to low-power operation with first and third transistors 110 and 130 biased in class AB and class C, respectively, both at 28V drain voltage and second and fourth transistors 120 and 140 biased off, also at 28V drain voltage, show approximately 3-12 degrees increased AM-PM distortion compared to traces 860-864 corresponding to first and second transistors 110, 120, biased in class AB and third, and fourth transistors 130, 140 biased in class C, in the high-power state all biased with a 48V drain voltage.

In FIG. 8D graph 870 shows multi-stage stage drain efficiency in percent versus output power in dBm. At an output power of 35 dBm, traces 886-889 corresponding to low-power operation with first and third transistors 110 and 130 biased in class AB and class C, respectively, both at 28V drain voltage and second and fourth transistors 120 and 140 biased off, also at 28V drain voltage, show approximately 10-12 percentage points higher efficiency than traces 880-884 corresponding to first and second transistors 110, 120, biased in class AB and third and fourth transistors 130, 140 biased in class C in the high-power state, all biased with a 48V drain voltage.

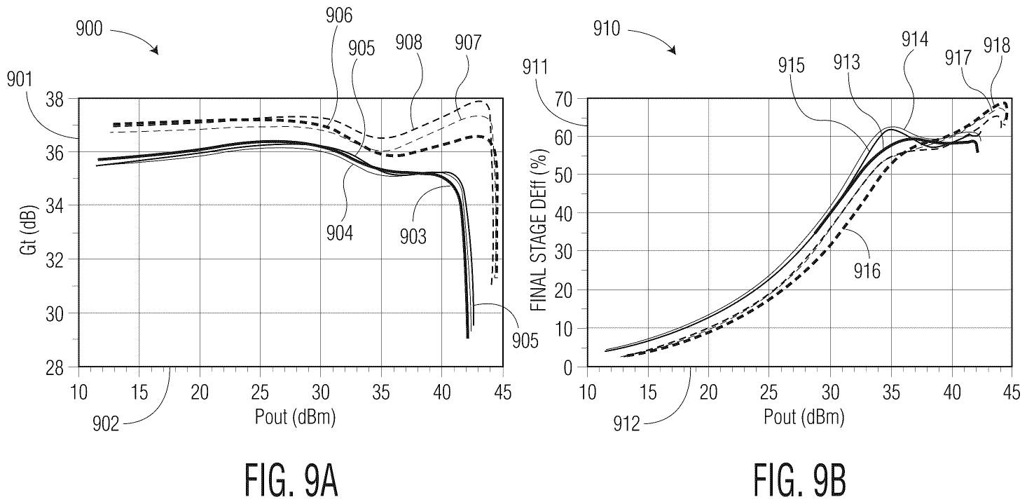

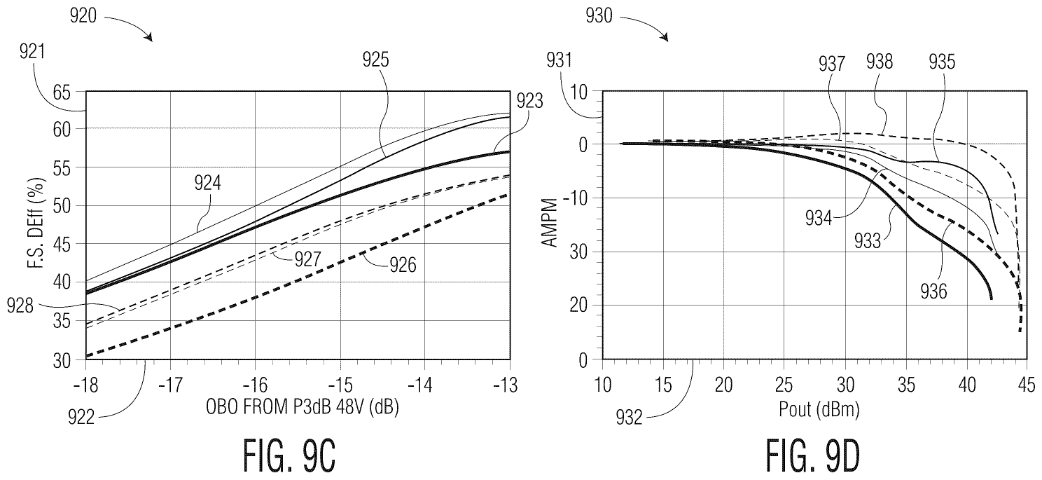

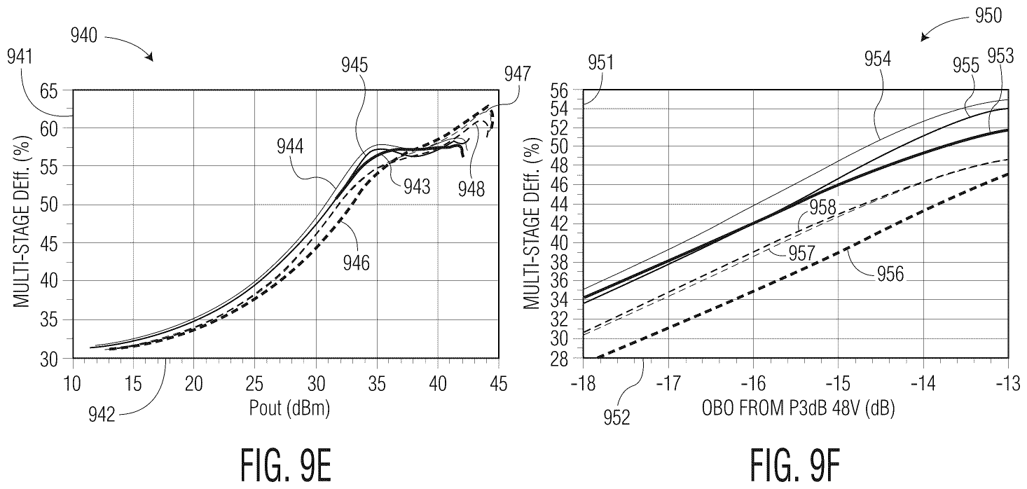

FIGS. 9A, 9B, 9C, 9D, 9E, and 9F, referred to collectively as FIG. 9, are graphical representations 900, 910, 920, 930, 940, 950 depicting simulated operation of the apparatus 500 of FIG. 5. According to an embodiment, graphs 900, 910, 920, 930, 940, and 950 depict gain, final stage drain efficiency, AM-PM, final stage drain efficiency, multi-stage drain efficiency, and three stage drain efficiency in low-power mode (i.e. first and third transistors 110, 130 operating in class AB and class C and second and fourth transistors 120, 140 are biased off) to apparatus 500 configured with all transistors active at 28V to compare performance. Traces 903, 904, 905, 906, 907, 908, 913, 914, 915, 916, 917, 918, 923, 924, 925, 926, 927, 928, 933, 934, 935, 936, 937, 938, 943, 944,945,946,947,948,953,954,955, 956, 957, and 958 are arranged so that each trio of traces (e.g. 903-905, 906-908, 913-915, 916-918, 923-925, 926-928, 933-935, 936-938, 943-945, 946-948, 953-955, and 956-958) represent performance at 2.5 GHz, 2.6 GHz, and 2.7 GHz, respectively. Here, like the traces of FIG. 8 in the low-power mode, bias conditions include a 28V bias applied to drain terminals 114, 124, 134, 144 of first and second power amplifier devices 300 and 400 with a quiescent current (I_{DQ}) of 8.5 mA for first transistor 110, 0 mA for second transistor 120 due to a gate bias of −8V applied to second gate 122 through second bias network 380 for the first power amplifier device 300 and a gate bias of −3.9V applied to third gate terminal 132 of third transistor 130, and a gate bias of −8V applied to gate of fourth transistor 140, according to an embodiment.

In FIG. 9A, graph 900 shows transducer gain (G_{T}) 901 expressed in dB versus output power 902 in dBm. Traces 903-905 corresponding to low-power operation with first and third transistors 110 and 130 biased in class AB and class C, respectively, both at 28V drain voltage and second and fourth transistors 120 and 140 biased off, also at 28V drain voltage show approximately 1 dB less gain from 15 to 40 dBm output power than traces 906-908 corresponding to first and second transistors 110, 120 biased in class AB and third and fourth transistors, 130, 140 biased in class C, all biased at 28 V drain voltage in the high-power state.

In FIG. 9B, graph 910 shows final stage drain efficiency 911 in percent, versus output power 912 in dBm. At an output power of 35 dBm, traces 913-915 corresponding to low-power operation with first and third transistors 110 and 130 biased in class AB and class C, respectively, both at 28V drain voltage second and fourth transistors 120 and 140 biased off, also at 28V drain voltage show approximately 3-5 percentage points higher efficiency than traces 916-918 corresponding to first and second transistors 110, 120 biased in class AB and third and fourth transistors, 130, 140 biased in class C, all biased at 28 V drain voltage in the high-power state.

In FIG. 9C, graph 920 shows final stage drain efficiency 921 in percent versus output backed off power (OBO) 922 in dB with the saturated power of high-power 48V state of FIG. 8 as a reference. Traces 923-925 corresponding to low-power operation with first and third transistors 110 and 130 biased in class AB and class C, respectively, both at 28V drain voltage and second and fourth transistors 120 and 140 biased off, also at 28V drain voltage, show approximately 5-10 percentage points higher efficiency as a function of back-off power than traces 926-928 corresponding to first and second transistors 110, 120 biased in class AB and third and fourth transistors, 130, 140 biased in class C, all biased at 28 V drain voltage in the high-power state.

In FIG. 9D, graph 930 shows insertion phase modulation in degrees in response to amplitude modulation (AM-PM) 931 versus output power 932 in dBm. Traces 933-935 corresponding to low-power operation with first and third transistors 110 and 130 biased in class AB and class C, respectively, both at 28V drain voltage and second and fourth transistors 120 and 140 biased off, also at 28V drain voltage, show approximately 3-5 degrees increased AM-PM distortion compared to traces 936-938 corresponding to first and second transistors 110, 120 biased in class AB and third and fourth transistors, 130, 140 biased in class C, all biased at 28 V drain voltage in the high-power state.

In FIG. 9E, graph 940 shows multi-stage drain efficiency 941 in percent, versus output power 942 in dBm. At an output power of 35 dBm, traces 943-945 corresponding to low-power operation with first and third transistors 110 and 130 biased in class AB and class C, respectively, both at 28V drain voltage and second and fourth transistors 120 and 140 biased off, also at 28V drain voltage, show approximately three percentage points higher efficiency than traces 946-948 corresponding to first and second transistors 110, 120 biased in class AB and third and fourth transistors, 130, 140 biased in class C, all biased at 28 V drain voltage in the low-power state.

In FIG. 9F, graph 950 shows multi-stage drain efficiency 951 in percent, versus output power back off 952 in dB with the saturated output power of the 48V high-power state as a reference. At a 10 dB back off level, traces 953-955 corresponding to low-power operation with first and third transistors 110 and 130 biased in class AB and class C, respectively, both at 28V drain voltage and second and fourth transistors 120 and 140 biased off also at 28V drain voltage, show approximately 4-5 percentage points higher efficiency than traces 956-958 corresponding to first and second transistors 110, 120 biased in class AB and third and fourth transistors, 130, 140 biased in class C, all biased at 28 V drain voltage in the high-power state.

An amplifier device includes a first input terminal, a second input terminal, a first transistor having a first control electrode and first and second current-carrying electrodes, wherein the first control electrode is radio frequency (RF) coupled to the first input terminal and DC-coupled to a first bias network electrically coupled to the first control electrode, wherein the first bias network is configured to apply a first direct current (DC) bias to the first control electrode and is RF-isolated from the first control electrode. The amplifier device further includes a second transistor that includes a second control electrode that is RF coupled to the second input terminal and a second bias network electrically coupled to the second transistor, wherein the second bias network is configured to apply a second DC bias to the second transistor and is RF-isolated from the second transistor.

For the sake of brevity, certain terminology may also be used herein for the purpose of reference only, and thus are not intended to be limiting, and the terms “first,” “second” and other such numerical terms referring to structures do not imply a sequence or order unless clearly indicated by the context.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with) another element, and not necessarily mechanically. Thus, although the schematic shown in the figures depict one exemplary arrangement of elements, additional intervening elements, devices, features, or components may be present in an embodiment of the depicted subject matter.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

1-14. (canceled)

15. An amplifier device comprising:
a first amplifier electrically coupled to a first input terminal and to a first output terminal, wherein the first amplifier includes:
a first transistor that includes a first control electrode, a first current-carrying electrode, and a second current-carrying electrode, wherein the first transistor is configured to support a current flow between the first current-carrying electrode and the second current-carrying electrode, wherein the first control electrode is configured to control the current flow between the first current-carrying electrode and the second current-carrying electrode, wherein the first control electrode is electrically coupled to the first input terminal, and wherein the first current-carrying electrode is electrically coupled to the first output terminal,
a first bias network electrically coupled to the first control electrode, wherein the first bias network is configured to apply a first direct current (DC) bias voltage to the first control electrode, and the first bias network is radio frequency (RF) isolated from the first control electrode,
a second transistor that includes a second control electrode, a third current-carrying electrode and a fourth current-carrying electrode, wherein the second transistor is configured to support a current flow between the third current-carrying electrode and the fourth current-carrying electrode, wherein the second control electrode is configured to control the current flow between the third current-carrying electrode and the fourth current-carrying electrode, wherein the second control electrode is electrically coupled to the first input terminal, and wherein the third current-carrying electrode is electrically coupled to the first output terminal, and
a second bias network electrically coupled to the second control electrode, wherein the second bias network is configured to apply a second DC bias voltage to the second control electrode, and the second bias network is RF-isolated from the second control electrode.

16. The amplifier device of claim 15, further comprising:
a second amplifier electrically coupled to a second input terminal and a second output terminal, wherein the second amplifier includes:
a third transistor that includes a third control electrode, a fifth current-carrying electrode and a sixth current-carrying electrode, wherein the third transistor is configured to support a current flow between the fifth current-carrying electrode and the sixth current-carrying electrode, wherein the third control electrode is configured to control the current flow between the fifth current-carrying electrode and the sixth current-carrying electrode, wherein the third control electrode is electrically coupled to the second input terminal, and wherein the fifth current-carrying electrode is electrically coupled to the second output terminal,
a third bias network electrically coupled to the third control electrode, wherein the third bias network is configured to apply a third DC bias voltage to the third control electrode, and wherein the third bias network is RF-isolated from the third control electrode,
a fourth transistor that includes a fourth control electrode, a seventh current-carrying electrode and an eighth current-carrying electrode, wherein the fourth transistor is configured to support a current flow between the seventh current-carrying electrode and the eighth current-carrying electrode, wherein the fourth control electrode is configured to control the current flow between the seventh current-carrying electrode and the eighth current-carrying electrode, wherein the fourth control electrode is electrically coupled to the second input terminal, and wherein the seventh current-carrying electrode is electrically coupled to the second output terminal, and
a fourth bias network electrically coupled to the fourth control electrode, wherein the fourth bias network is configured to apply a fourth DC bias voltage to the fourth control electrode, and wherein the fourth bias network is RF-isolated from the fourth control electrode.

17. The amplifier device of claim 16, further comprising:
a transmission line characterized by a phase shift and an impedance transformation, wherein the transmission line is electrically coupled to the first output terminal; and
a summing node electrically coupled to the transmission line and to the second output terminal.

18. The amplifier device of claim 17, further comprising:
a splitter having a splitter input, a first splitter output, and a second splitter output, wherein the splitter is configured to divide a first signal delivered to the splitter input into a second signal at the first splitter output and a third signal at the second splitter output with a phase difference between the second signal and the third signal, wherein a difference between the phase difference and the phase shift of the transmission line is less than twenty percent, wherein the first input terminal is electrically coupled to the first splitter output, and the second input terminal is electrically coupled to the second splitter output.

19. The amplifier device of claim 18, wherein the first amplifier is configured as a carrier amplifier and the second amplifier is configured as a peaking amplifier in a Doherty amplifier configuration.

20. The amplifier device of claim 15, wherein the first amplifier is configured to operate in a first state and to operate in a second state, wherein:
when in the first state, the first transistor and the second transistor are configured to operate with a first bias voltage applied to the first bias network, and a second bias voltage applied to the second bias network such that the first bias voltage and the second bias voltage allow an RF current of at least fifty percent of a maximum current of the second transistor to flow through the second transistor when the first transistor is operated at a saturated output power, and a third bias voltage applied to the first current-carrying electrode and to the third current-carrying electrode; and
when in the second state, the first transistor and the second transistor are configured to operate with the first bias voltage applied to the first bias network, and a fourth bias voltage applied to the second bias network such that the fourth bias voltage allows an RF current of less than ten percent of a maximum current of the second transistor to flow from the third current-carrying electrode of the second transistor to the fourth current-carrying electrode of the second transistor when the first transistor is operated at a saturated output power with a current of greater than fifty percent of a maximum current of the first transistor, and a fifth bias voltage applied to the first current-carrying electrode and to the third current-carrying electrode.

21. The amplifier device of claim 15, wherein the first transistor is a field effect transistor, wherein:
the first control electrode is a gate electrode;
the first current-carrying electrode is a drain electrode; and
the second current-carrying electrode is a source electrode.

22. The amplifier device of claim 15, further comprising:
a first coupling element having a first terminal and a second terminal, wherein the second terminal is electrically coupled to the first control electrode; and
a second coupling element having a third terminal and a fourth terminal, wherein the fourth terminal is electrically coupled to the second control electrode, and wherein the first terminal is electrically coupled to the third terminal.

23. The amplifier device of claim 22, further comprising:
a driver amplifier comprising a transistor, which is electrically coupled to the first terminal of the first coupling element and to the third terminal of the second coupling element.

24. The amplifier device of claim 22, further comprising:
a first input matching network, configured to provide an impedance match for the first transistor at a fundamental frequency, wherein the first input matching network is coupled to the first control electrode; and
a second input matching network, configured to provide an impedance match for the second transistor at the fundamental frequency, wherein the second input matching network is coupled to the second control electrode.

25. The amplifier device of claim 22, further comprising:
a first input harmonic matching network, configured to provide a harmonic termination for the first transistor at a harmonic frequency; and
a second harmonic matching network, configured to provide a harmonic termination for the second transistor at the harmonic frequency.

26. A power amplifier device comprising:
a first amplifier electrically coupled to a first input terminal and to a first output terminal, wherein the first amplifier includes:
a first field effect transistor that includes a first gate electrode, a first drain electrode and a first source electrode, wherein the first field effect transistor is configured to support a current flow between the first drain electrode and the first source electrode, wherein the first gate electrode is configured to control the current flow between the first drain electrode and the first source electrode, wherein the first gate electrode is electrically coupled to the first input terminal, and wherein the first drain electrode is electrically coupled to the first output terminal,
a first bias network electrically coupled to the first gate electrode, wherein the first bias network is configured to apply a first direct current (DC) bias voltage to the first gate electrode, and the first bias network is radio frequency (RF)-isolated from the first gate electrode,
a second field effect transistor that includes a second gate electrode, a second drain electrode and a second source electrode, wherein the second field effect transistor is configured to support a current flow between the second drain electrode and the second source electrode, wherein the second gate electrode is configured to control the current flow between the second drain electrode and the second source electrode, wherein the second gate electrode is electrically coupled to the first input terminal, and wherein the second source electrode is electrically coupled to the first output terminal,
a second bias network electrically coupled to the second gate electrode, wherein the second bias network is configured to apply a second DC bias voltage to the second gate electrode, and the second bias network is RF-isolated from the second gate electrode,
a first capacitor having a first terminal and a second terminal, wherein the second terminal is electrically coupled to the first gate electrode,
a second capacitor having a third terminal and a fourth terminal, wherein the fourth terminal is electrically coupled to the second gate electrode, and wherein the first terminal is electrically coupled to the third terminal,
a first input matching network electrically coupled to the first gate electrode and configured to provide an impedance match for the first field effect transistor at a fundamental frequency, and
a second input matching network electrically coupled to the second gate electrode and configured to provide an impedance match for the second field effect transistor at the fundamental frequency.

27. The power amplifier device of claim 26, further comprising:
a second amplifier electrically coupled to a second input terminal and a second output terminal, wherein the second amplifier includes:
a third transistor that includes a third gate electrode, a third drain electrode and a third source electrode, wherein the third transistor is configured to support a current flow between the third drain electrode and the third source electrode, wherein the third gate electrode is configured to control the current flow between the third drain electrode and the third source electrode, wherein the third gate electrode is electrically coupled to the second input terminal, and wherein the third drain electrode is electrically coupled to the second output terminal,
a third bias network electrically coupled to the third gate electrode, wherein the third bias network is configured to apply a third DC bias voltage to the third gate electrode and is RF-isolated from the third gate electrode,
a fourth transistor that includes a fourth gate electrode, a fourth drain electrode and a fourth source electrode, wherein the fourth transistor is configured to support a current flow between the fourth drain electrode and the fourth source electrode, wherein the fourth gate electrode is configured to control the current flow between the fourth drain electrode and the fourth source electrode, wherein the fourth gate electrode is radio electrically coupled to the second input terminal, and wherein the fourth drain electrode is electrically coupled to the second output terminal, and
a fourth bias network electrically coupled to the fourth gate electrode, wherein the fourth bias network is configured to apply a fourth DC bias voltage to the fourth gate electrode, and the fourth bias network is RF-isolated from the fourth gate electrode;
a transmission line characterized by a phase shift and an impedance transformation, wherein the transmission line is electrically coupled to the first output terminal;
a summing node electrically coupled to the transmission line and to the second output terminal; and
a splitter having a splitter input, a first splitter output, and a second splitter output, wherein the splitter is configured to divide a first signal delivered to the splitter input into a second signal at the first splitter output and a third signal at the second splitter output with a phase difference between the second signal and the third signal, wherein a difference between the phase difference and the phase shift of the transmission line is less than twenty percent, wherein the first input terminal is electrically coupled to the first splitter output, and the second input terminal is electrically coupled to the second splitter output, and
wherein the first amplifier is configured as a carrier amplifier and the second amplifier is configured as a peaking amplifier in a Doherty amplifier configuration.

28. The power amplifier device of claim 26, further comprising:
a first input harmonic matching network, configured to provide a harmonic termination for the first field effect transistor at a harmonic frequency; and
a second harmonic matching network, configured to provide a harmonic termination for the second field effect transistor at the harmonic frequency.

29. The power amplifier device of claim 26, further comprising:
a driver amplifier comprising a transistor, which is electrically coupled to the first terminal of the first capacitor and to the third terminal of the second capacitor.

30. An apparatus comprising:
a base substrate;
a first amplifier die coupled to the base substrate and electrically coupled to a first input terminal and to a first output terminal, wherein the first amplifier die includes:
a first field effect transistor that includes a first gate electrode, a first drain electrode and a first source electrode, wherein the first field effect transistor is configured to support a current flow between the first drain electrode and the first source electrode, wherein the first gate electrode is configured to control the current flow between the first drain electrode and the first source electrode, wherein the first gate electrode is electrically coupled to the first input terminal, and wherein the first drain electrode is electrically coupled to the first output terminal,
a first bias network electrically coupled to the first gate electrode, wherein the first bias network is configured to apply a first direct current (DC) bias voltage to the first gate electrode, and the first bias network is radio frequency (RF)-isolated from the first gate electrode,
a second field effect transistor that includes a second gate electrode, a second drain electrode and a second source electrode, wherein the second field effect transistor is configured to support a current flow between the second drain electrode and the second source electrode, wherein the second gate electrode is configured to control the current flow between the second drain electrode and the second source electrode, wherein the second gate electrode is electrically coupled to the first input terminal, and wherein the second source electrode is electrically coupled to the first output terminal,
a second bias network electrically coupled to the second gate electrode, wherein the second bias network is configured to apply a second DC bias voltage to the second gate electrode, and the second bias network is RF-isolated from the second gate electrode,
a first capacitor having a first terminal and a second terminal, wherein the second terminal is electrically coupled to the first gate electrode,
a second capacitor having a third terminal and a fourth terminal, wherein the fourth terminal is electrically coupled to the second gate electrode, and wherein the first terminal is electrically coupled to the third terminal, and
a first input matching network electrically coupled to the first gate electrode and configured to provide an impedance match for the first field effect transistor at a fundamental frequency.

31. The apparatus of claim 30, wherein the first field effect transistor and the second field effect transistor are formed on a first substrate, and wherein the first capacitor and the second capacitor are formed on the first substrate.

32. The apparatus of claim 30, wherein the first field effect transistor and the second field effect transistor are formed on a first substrate, and wherein the first capacitor and the second capacitor are formed on a second substrate.

33. The apparatus of claim 32, further comprising:
a driver amplifier comprising a transistor, which is formed on the second substrate, wherein the driver amplifier is electrically coupled to the first terminal of the first capacitor and to the third terminal of the second capacitor, and wherein the first bias network is formed on the second substrate and the second bias network is formed on the second substrate.

34. The apparatus of claim 30, further comprising:
a second amplifier coupled to the base substrate and electrically coupled to a second input terminal and a second output terminal, wherein the second amplifier includes:
a third transistor that includes a third gate electrode, a third drain electrode and a third source electrode, configured to support a current flow between the third drain electrode and the third source electrode, wherein the third gate electrode is configured to control the current flow between the third drain electrode and the third source electrode, wherein the third gate electrode is electrically coupled to the second input terminal, and wherein a third drain electrode is electrically coupled to the second output terminal,
a third bias network electrically coupled to the third gate electrode, wherein the third bias network is configured to apply a third DC bias voltage to the third gate electrode and is RF-isolated from the third gate electrode,
a fourth transistor that includes a fourth gate electrode, a fourth drain electrode and a fourth source electrode, configured to support a current flow between the fourth drain electrode and the fourth source electrode, wherein the fourth gate electrode is configured to control the current flow between the fourth drain electrode and the fourth source electrode, wherein the fourth gate electrode is electrically coupled to the second input terminal, and wherein the fourth drain electrode is electrically coupled to the second output terminal, and
a fourth bias network electrically coupled to the fourth gate electrode, wherein the fourth bias network is configured to apply a fourth DC bias voltage to the fourth gate electrode and is RF-isolated from the fourth gate electrode;
a transmission line formed over the base substrate having a phase shift and configured to electrically couple the first output terminal and the second output terminal;
an impedance transformer formed over the base substrate and electrically coupled to a summing node at the group consisting of the first output terminal and the second output terminal; and
a splitter device formed over the base substrate having a splitter input and a first splitter output and a second splitter output and configured to divide a signal delivered to the splitter input between the first splitter output and the second splitter output with a splitter phase difference between the first splitter output and the second splitter output, wherein a difference between the splitter phase difference and the phase shift of the transmission line is less than twenty percent, wherein the first input terminal is electrically coupled to the first splitter output and the second input terminal is electrically coupled to the second splitter output, and
wherein the first amplifier is configured as a carrier amplifier and the second amplifier is configured as a peaking amplifier in a Doherty amplifier configuration.
